(19) United States
(12) Patent Application Publication
(10) Pub. No.: US 2026/0269563 A1
(43) Pub. Date: Sep. 10, 2026

(54) SEMICONDUCTOR OPTICAL MODULATOR, SEMICONDUCTOR OPTICAL INTEGRATED DEVICE, AND SEMICONDUCTOR OPTICAL APPARATUS

(71) Applicant: Lumentum Operations LLC., San Jose, CA (US)

(72) Inventors: Takanori SUZUKI, Tokyo (JP); Shuhei OHNO, Kanagawa (JP); Ryosuke HATAI, Kanagawa (JP)

(21) Appl. No.: 19/286,553

(22) Filed: Jul. 31, 2025

(30) Foreign Application Priority Data
Mar. 7, 2025 (JP) 2025036499
Apr. 25, 2025 (JP) 2025073466

(51) Int. Cl. H01S 5/026; H01S 5/02345; H01S 5/042; H01S 5/227

(52) U.S. Cl. CPC H01S 5/0265; H01S 5/04256; H01S 5/227; H01S 5/02345

(57) ABSTRACT

Provided is a semiconductor optical modulator including: a semiconductor multilayer including a first conductivity type semiconductor layer, an optical functional layer, and a second conductivity type semiconductor layer which are grown in the stated order; a first electrode connected to the first conductivity type semiconductor layer; and a second electrode connected to the second conductivity type semiconductor layer, wherein a part of the first conductivity type semiconductor layer, the optical functional layer, and the second conductivity type semiconductor layer form a mesa structure extending in an extending direction, and wherein the first conductivity type semiconductor layer has a width narrower than a width of the semiconductor optical modulator.

### CROSS-REFERENCE TO RELATED APPLICATION

This Patent Application claims priority to Japan Patent Application No. JP2025-073466, filed on Apr. 25, 2025, and Japan Patent Application No. JP 2025-036499, filed on Mar. 7, 2025. The disclosure of the prior Application is considered part of and is incorporated by reference into this Patent Application.

### TECHNICAL FIELD

The present disclosure relates generally to a semiconductor optical modulator, a semiconductor optical integrated device, and a semiconductor optical apparatus.

### BACKGROUND

A type of semiconductor optical apparatus used in optical communication includes a modulator for converting input light into a modulated optical signal. For example, a modulator integrated laser device can include a modulator section in which an anode electrode and a cathode electrode are arranged on a surface and differential signals are input to those two electrodes.

### SUMMARY

As an example of a structure of a modulator, there can be a structure in which, on a substrate, an n-type semiconductor layer, an absorption layer, and a p-type semiconductor layer are grown in the stated order. Further, those layers have a mesa structure having a width narrower than a width of the substrate in a direction perpendicular to an optical axis. The absorption layer and the p-type semiconductor layer are arranged only in the mesa structure. Additionally, the n-type semiconductor layer has a part arranged in the mesa structure, but another part of the n-type semiconductor layer close to the substrate is arranged also on a lateral side of the mesa structure. The anode electrode is connected to the p-type semiconductor layer on an upper surface of the mesa structure, and the cathode electrode is connected to the n-type semiconductor layer on the lateral side of the mesa structure. Accordingly, the structure from a connection portion between an electrode and a semiconductor layer to the absorption layer is different between the anode side and the cathode side. This difference causes a difference between a frequency characteristic from the anode electrode to the absorption layer and a frequency characteristic from the cathode electrode to the absorption layer. This difference in frequency characteristic causes, for example, at the time of applying differential signals to the anode electrode and the cathode electrode, a difference between a transmission condition (amplitude, phase, or the like) of an electrical signal on the anode side and a transmission condition of an electrical signal on the cathode side, thereby affecting the characteristic of the modulator as a result. This issue is caused not only in an electro-absorption, but also in a direct-modulation laser.

Some implementations described herein include a semiconductor optical modulator that has an excellent characteristic.

In some implementations, a semiconductor optical modulator includes: a semiconductor multilayer including a first conductivity type semiconductor layer, an optical functional layer, and a second conductivity type semiconductor layer which are grown in the stated order; a first electrode connected to the first conductivity type semiconductor layer; and a second electrode connected to the second conductivity type semiconductor layer, wherein a part of the first conductivity type semiconductor layer, the optical functional layer, and the second conductivity type semiconductor layer form a mesa structure extending in an extending direction, and wherein the first conductivity type semiconductor layer has a width narrower than a width of the semiconductor optical modulator.

### BRIEF DESCRIPTION OF THE DRAWINGS

FIG. 1 is a top view of a semiconductor optical modulator according to a first example implementation of the present invention.

FIG. 2 is a cross-sectional view taken along the line II-II of the semiconductor optical modulator illustrated in FIG. 1.

FIG. 3 is a cross-sectional view taken along the line III-III of the semiconductor optical modulator illustrated in FIG. 1.

FIG. 4 is a top view for illustrating a cross section taken along the line A-A of the semiconductor optical modulator illustrated in FIG. 2 and FIG. 3.

FIG. 5 is a cross-sectional view of a semiconductor optical modulator according to a second example implementation of the present invention.

FIG. 6 is a top view for illustrating a cross section taken along the line A-A of the semiconductor optical modulator illustrated in FIG. 5.

FIG. 7 is a top view of a semiconductor optical modulator according to a modification example of the second example implementation.

FIG. 8 is a top view of a semiconductor optical modulator according to a third example implementation of the present invention.

FIG. 9 is a cross-sectional view taken along the line IX-IX of the semiconductor optical modulator illustrated in FIG. 8.

FIG. 10 is a top view of a semiconductor optical modulator according to a fourth example implementation of the present invention.

FIG. 11 is a top view for illustrating a cross section taken along the line XI-XI of the semiconductor optical modulator illustrated in FIG. 10.

FIG. 12 is a top view of a semiconductor optical modulator according to a fifth example implementation of the present invention.

FIG. 13 is a cross-sectional view taken along the line XIII-XIII of the semiconductor optical modulator illustrated in FIG. 12.

FIG. 14 is a top view of a semiconductor optical integrated device according to a sixth example implementation of the present invention.

FIG. 15 is a cross-sectional view taken along the line B-B of the semiconductor optical integrated device illustrated in FIG. 14.

FIG. 16 is a top view of a semiconductor optical integrated device according to a seventh example implementation of the present invention.

FIG. 17 is a cross-sectional view taken along the line XVII-XVII of the semiconductor optical integrated device illustrated in FIG. 16.

FIG. 18 is a cross-sectional view taken along the line XVIII-XVIII of the semiconductor optical integrated device illustrated in FIG. 16.

FIG. 19 is a top view of a semiconductor optical apparatus according to an eighth example implementation of the present invention.

### DETAILED DESCRIPTION

A specific and detailed description is given below on example implementations of the present invention with reference to the drawings. Members denoted by the same reference symbol throughout the drawings have the same or an equivalent function, and a repetitive description on the members is omitted. Note that sizes of graphics are not always to scale.

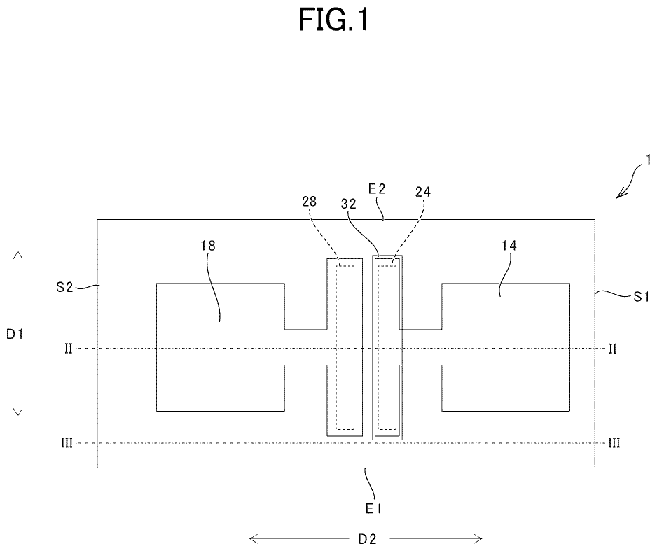

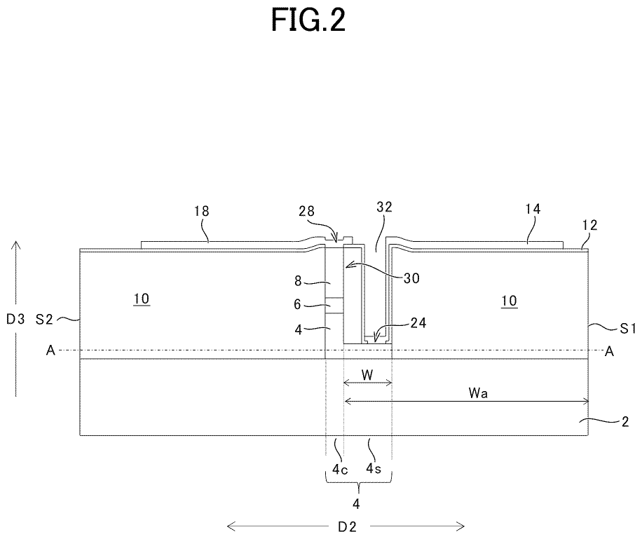

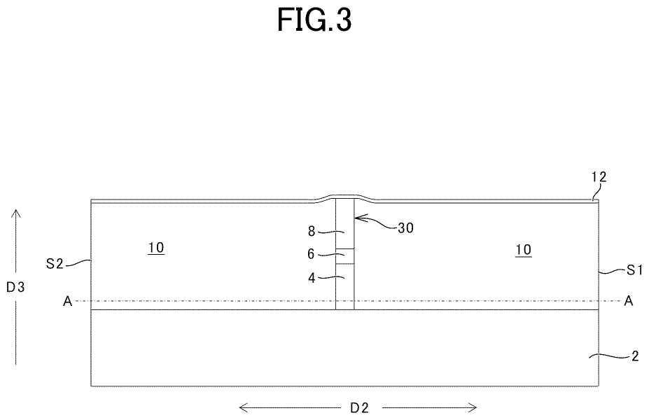

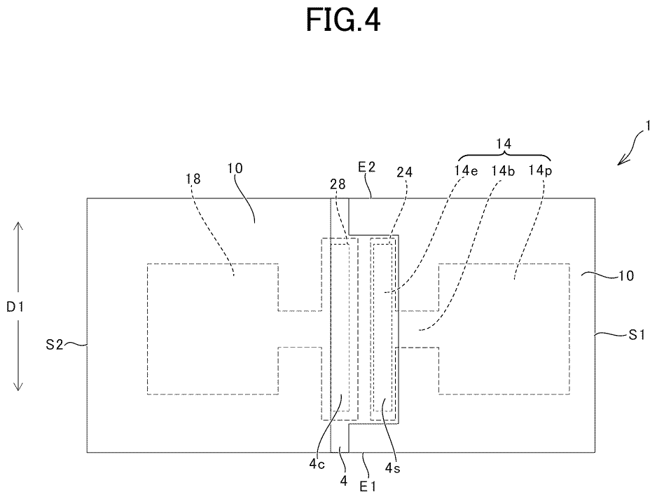

FIG. 1 is a top view of a semiconductor optical modulator 1 according to a first example implementation of the present invention. FIG. 2 is a cross-sectional view for schematically illustrating a cross section taken along the line II-II of FIG. 1. FIG. 3 is a cross-sectional view for schematically illustrating a cross section taken along the line III-III of FIG. 1. FIG. 4 is a top view for schematically illustrating a cross section taken along the line A-A of FIG. 2 and FIG. 3.

The semiconductor optical modulator 1 may include a semiconductor multilayer including a first conductivity type semiconductor layer 4, an optical functional layer 6, and a second conductivity type semiconductor layer 8 which may be grown in the stated order on a substrate 2 which may be a semi-insulating semiconductor. In this case, the first conductivity type may be an n-type, and the second conductivity type may be a p-type, but the types may be reversed. A part of the first conductivity type semiconductor layer 4, the optical functional layer 6, and the second conductivity type semiconductor layer 8 include a mesa structure 30 extending in an extending direction D1. The extending direction D1 is also an optical axis direction. A buried layer 10 is arranged on each of both lateral sides of the mesa structure 30 in a width direction D2 of the mesa structure 30, which is perpendicular to the extending direction D1. The semiconductor optical modulator 1 may include, on its surface, a first electrode 14 and a second electrode 18. A part of the first electrode 14 may be arranged on the surface of the semiconductor optical modulator 1 on a right side (one side) of the mesa structure 30 in the width direction D2. A part of the second electrode 18 may be arranged on the surface of the semiconductor optical modulator 1 on a left side (another side) of the mesa structure 30 in the width direction D2. Another part of the second electrode 18 may be arranged on the mesa structure 30. The part of the first electrode 14 may be arranged on the left side, and the part of the second electrode 18 may be arranged on the right side. As another example, both of the first electrode 14 and the second electrode 18 may be arranged on any one of the right side or the left side of the mesa structure 30 in the width direction D2. The first electrode 14 and the second electrode 18 may be metal layers. The semiconductor optical modulator 1 may include an insulating film 12. A normal direction to the substrate 2 is referred to as “stacking direction D3.” The following description is given while the stacking direction D3 is set as an up-down direction.

The first conductivity type semiconductor layer 4 may include a middle portion 4c and a first lateral portion 4s. The middle portion 4c may be formed of a part forming the mesa structure 30, and a part which may be continuous with a lower side of the part forming the mesa structure 30 and may have the same width as the width of the mesa structure 30. The first lateral portion 4s may be continuous with the middle portion 4c on the right side of the mesa structure 30. The buried layer 10 may include a groove portion 32, and the first conductivity type semiconductor layer 4 may be arranged on the lower side of the bottom of the groove portion 32. The insulating film 12 may be arranged in a part of a bottom surface of the groove portion 32 and a side surface of the groove portion 32, but the insulating film 12 may not be arranged in another part of the bottom surface of the groove portion. In a part of the bottom surface of the groove portion 32 in which the insulating film 12 is not arranged, the first electrode 14 may be electrically and physically connected to the first conductivity type semiconductor layer 4. A region in which the first electrode 14 and the first conductivity type semiconductor layer 4 are connected to each other in plan view is hereinafter referred to as “first connection region 24.” The phrase “in plan view” herein refers to a case of viewing along the stacking direction D3. For the sake of description, in FIG. 1, the first connection region 24 is indicated by the broken line. The first lateral portion 4s may be provided in the first connection region 24 in plan view. Further, the first electrode 14 may include a first conducting electrode portion 14e, a first bridge electrode portion 14b, and a first pad electrode portion 14p. The first conducting electrode portion 14e may be arranged above the first connection region 24. The first bridge electrode portion 14b may be continuous with the first conducting electrode portion 14e and extends in the width direction D2. The first pad electrode portion 14p may be continuous with the first bridge electrode portion 14b. The first pad electrode portion 14p may be arranged above the buried layer 10. The first pad electrode portion 14p may be connected to external electric wiring (not shown). A dimension of the first bridge electrode portion 14b in the extending direction D1 may be narrower than dimensions of the first conducting electrode portion 14e and the first pad electrode portion 14p in the extending direction D1.

The insulating film 12 is not arranged in a part of the upper surface of the mesa structure 30. In a region of the upper surface of the mesa structure 30 in which the insulating film 12 is not arranged, the second electrode 18 may be electrically and physically connected to the second conductivity type semiconductor layer 8. A region in which the second electrode 18 and the second conductivity type semiconductor layer 8 are connected to each other in plan view is hereinafter referred to as “second connection region 28.” For the sake of description, in FIG. 1, the second connection region 28 is indicated by the broken line. A width of the second connection region 28 may be the same as or different from the width of the mesa structure 30.

In this case, the semiconductor optical modulator 1 is an electro-absorption modulator. The optical functional layer 6 is a layer for absorbing light in accordance with a voltage applied between the first electrode 14 and the second electrode 18. The optical functional layer 6 may include a plurality of layers. For example, the optical functional layer 6 may include a multiple quantum well (MQW) layer and optical confinement layers arranged above and below the multiple quantum well (MQW) layer. The second conductivity type semiconductor layer 8 may include a plurality of layers. For example, the second conductivity type semiconductor layer 8 may have a structure including a cladding layer and a contact layer arranged above the cladding layer. When the semiconductor optical modulator 1 is a direct-modulation semiconductor laser, the optical functional layer 6 is a light emitting layer.

The semiconductor optical modulator 1 may include a first facet E1 and a second facet E2 which are each a facet in the extending direction D1. Output light of an external light source (not shown) may be input from the first facet E1, and may be output as a modulated optical signal from the second facet E2. The input facet and the output facet may be reversed. Further, the semiconductor optical modulator 1 may include, in the width direction D2, a first side surface S1 which may be a side surface on a side on which the first electrode 14 is arranged (right side in FIG. 1 and FIG. 2), and a second side surface S2 which may be a side surface on a side on which the second electrode 18 is arranged (left side in FIG. 1 and FIG. 2).

FIG. 4 is a top view of a cross section taken along the line A-A of FIG. 2 and FIG. 3. For the sake of description, the first electrode 14, the second electrode 18, the first connection region 24, and the second connection region 28 may be indicated by the broken lines. The feature of the semiconductor optical modulator 1 according to the first example implementation resides in the shape of the first conductivity type semiconductor layer 4. That is, as described above, the first conductivity type semiconductor layer 4 may include the middle portion 4c and the first lateral portion 4s. A part of the first lateral portion 4s may be in contact with the first electrode 14. A side surface of the first lateral portion 4s does not reach the first side surface S1. In other words, a side surface of the first conductivity type semiconductor layer 4 is arranged on the inner side with respect to a side surface of the semiconductor optical modulator 1. The first conductivity type semiconductor layer 4 may include a plurality of layers.

Here, there is assumed a case in which differential electrical signals are input to the first electrode 14 and the second electrode 18. The electrical signal input to the first electrode 14 is transmitted to the first conductivity type semiconductor layer 4 in the first connection region 24, and is transmitted to the optical functional layer 6 via the first conductivity type semiconductor layer 4. This transmission route is hereinafter referred to as “first transmission route.” The electrical signal input to the second electrode 18 is transmitted to the second conductivity type semiconductor layer 8 in the second connection region 28, and is transmitted to the optical functional layer 6 via the second conductivity type semiconductor layer 8. This transmission route is hereinafter referred to as “second transmission route.” When the frequency characteristic of the first transmission route and the frequency characteristic of the second transmission route are different, a difference is caused between the transmission conditions of the electrical signals input to the upper side and the lower side of the optical functional layer 6. This difference causes deterioration of the frequency characteristic of the modulated optical signal.

The main cause of the difference in frequency characteristic is a difference between the structure of the first conductivity type semiconductor layer 4 and the structure of the second conductivity type semiconductor layer 8. In the first example implementation, main parts of the first conductivity type semiconductor layer 4 and the second conductivity type semiconductor layer 8 are formed of the same semiconductor material. However, the first conductivity type semiconductor layer 4 and the second conductivity type semiconductor layer 8 are different in physical size and conductivity, and hence a difference is caused between the frequency characteristic of the first conductivity type semiconductor layer 4 and the frequency characteristic of the second conductivity type semiconductor layer 8. For example, in another structure, the semiconductor layer on the anode side is arranged only in the mesa structure. Meanwhile, the semiconductor layer on the cathode side is arranged not only in the mesa structure but also to widely reach the side surface of the modulator integrated laser device. In the first example implementation, the size of the first conductivity type semiconductor layer 4 is brought close to the size of the second conductivity type semiconductor layer 8 so that the difference between the frequency characteristic of the first transmission route and the frequency characteristic of the second transmission route is reduced, resulting in that a semiconductor optical modulator having an excellent characteristic is achieved.

The width of the first conductivity type semiconductor layer 4 is narrower than the width of the semiconductor optical modulator 1. The first conductivity type semiconductor layer 4 includes the middle portion 4c and the first lateral portion 4s. The first lateral portion 4s has, in plan view, a minimum area required to include the first connection region 24. However, in the first example implementation, in consideration of manufacturing fluctuations, in plan view, the area of the first lateral portion 4s is larger than the area of the first connection region 24.

Further, it is preferred that the first connection region 24 and the mesa structure 30 be close to each other, whereas, from the viewpoint of manufacturing performance, it is preferred that the first connection region 24 and the mesa structure 30 be separated from each other to some extent. Specifically, it is desired that a width W of the first lateral portion 4 is be ⅓ or less of an interval Wa between a first mesa side surface which is a side surface of the mesa structure on the right side and the first side surface S1 which is a side surface of the semiconductor optical modulator 1 on the right side. The width W of the first lateral portion 4s is an interval between the first mesa side surface and a side surface of the first conductivity type semiconductor layer 4 on the right side in the width direction D2. In order to further reduce the frequency characteristic difference between the first transmission route and the second transmission route, it is desired that W be ¼ or less of Wa. As another example, it is desired that a side end of the first conductivity type semiconductor layer 4 on the right side overlap the first bridge electrode portion 14b in plan view.

As described above, the width of the first conductivity type semiconductor layer 4 is narrower than the width of the semiconductor optical modulator 1, and hence the first conductivity type semiconductor layer 4 is arranged only in a region close to the mesa structure 30, resulting in that the frequency characteristic difference between the first transmission route and the second transmission route is reduced. The middle portion 4c of the first conductivity type semiconductor layer 4 extends to reach the first facet E1 and the second facet E2 in the extending direction D1. The middle portion 4c is extended to reach the first facet E1 and the second facet E2 in consideration of propagation of light. The middle portion 4c is not required to reach the first facet E1 and/or the second facet E2. For example, another structure such as a window structure may be arranged on the exit facet side, and the window structure is not required to include the first conductivity type semiconductor layer 4.

Moreover, it is desired that, in the extending direction D1, both ends of the second connection region 28 be arranged on the inner side with respect to both ends of the first connection region 24. In this case, each end of the first connection region 24 in the extending direction D1 and each end of the second connection region 28 in the extending direction D1 are arranged on the same straight line in the width direction D2. In plan view, in the extending direction D1, the first connection region 24 and the second connection region 28 are disposed at the same position, and, in the width direction D2, the first connection region 24 and the second connection region 28 are arranged at positions shifted from each other. In the first example implementation, both ends of the first connection region 24 and both ends of the second connection region 28 do not reach the first facet E1 and the second facet E2, but the present invention is not limited thereto.

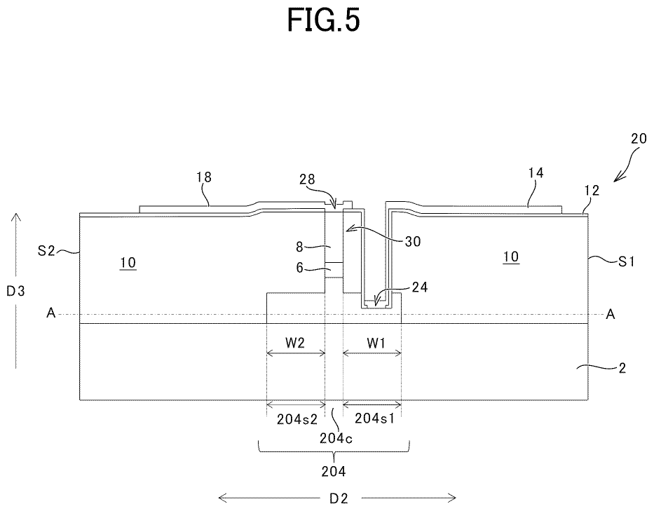

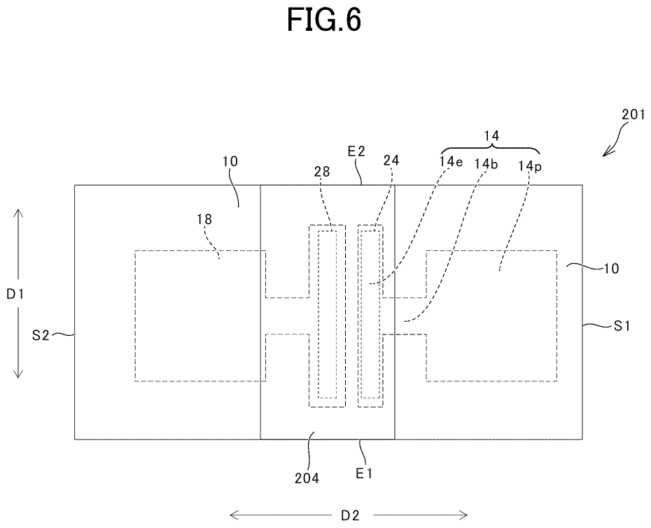

FIG. 5 is a cross-sectional view of a semiconductor optical modulator 201 according to a second example implementation of the present invention at a position corresponding to FIG. 2. FIG. 6 is a top view for schematically illustrating a cross section taken along the line A-A of FIG. 5. In FIG. 6, two electrodes and two connection regions are indicated by the broken lines similarly to FIG. 4 for the sake of description.

The difference between the semiconductor optical modulator 1 according to the first example implementation and the semiconductor optical modulator 201 according to the second example implementation resides in a shape of a first conductivity type semiconductor layer 204. The first conductivity type semiconductor layer 204 has a shape symmetrical in the width direction D2 with respect to the mesa structure 30. Further, the first conductivity type semiconductor layer 204 extends from the first facet E1 toward the second facet E2 in the same width in the extending direction D1. The first conductivity type semiconductor layer 204 includes a middle portion 204c, a first lateral portion 204s1, and a second lateral portion 204s2. The middle portion 204c is formed of a part forming the mesa structure 30, and a part which is continuous with a lower side of the part forming the mesa structure 30 and has the same width as the width of the mesa structure 30. The first lateral portion 204s1 is provided in the first connection region 24 in plan view, and is continuous with the middle portion 204c on the right side of the mesa structure 30. The second lateral portion 204s2 is continuous with the middle portion 204c on the left side of the mesa structure 30. The first lateral portion 204s1 is in contact with the first electrode 14 in the first connection region 24. The second lateral portion 204s2 is not in contact with any electrode.

As described in the first example implementation, from the viewpoint of the frequency characteristic, it is preferred that the first conductivity type semiconductor layer be smaller. However, from the viewpoint of the crystal quality of the buried layer 10, the second example implementation is superior. In the second example implementation, a procedure of forming the buried layer 10 is as follows. First, the mesa structure 30 and the first conductivity type semiconductor layer 204 are formed to have shapes illustrated in FIG. 5 and FIG. 6. Next, a mask is formed on the upper surface of the mesa structure 30. Then, the buried layer 10 is epitaxially grown. At this time, the buried layer 10 is not formed on the upper surface of the mesa structure 30 on which the mask is formed, and the buried layer 10 is formed in contact with the side surface of the first conductivity type semiconductor layer 204, the upper surface of the first conductivity type semiconductor layer 204, and the side surface of the mesa structure 30. At the time of the epitaxial growth of the buried layer 10, when the shape of the semiconductor layer serving as the base is asymmetrical in the width direction D2 with respect to the mesa structure 30, there is a fear that abnormality occurs in the shape of the buried layer 10. In the second example implementation, the second lateral portion 204s2 is arranged in order to avoid such abnormality of the shape of the buried layer 10. Also in the second example implementation, in the width direction D2, a width W1 of the first lateral portion 204s1 is preferably ⅓ or less of Wa, more preferably ¼ or less of Wa. Similarly, a width W2 of the second lateral portion 204s2 is preferably ⅓ or less of an interval between the side surface of the mesa structure 30 on the left side and the second side surface S2, more preferably ¼ or less of the interval.

In the width direction D2, it is desired that the width W1 of the first lateral portion 204s1 and the width W2 of the second lateral portion 204s2 be the same, but the width W1 of the first lateral portion 204s1 and the width W2 of the second lateral portion 204s2 may be different from each other. When a difference between the width W1 of the first lateral portion 204s1 and the width W2 of the second lateral portion 204s2 falls within 20% of W1 or W2, substantially no influence is caused on the crystal quality. Further, in the second example implementation, the width of the first conductivity type semiconductor layer 204 is the same in the entire part in the extending direction D1, but a width of a part of the first conductivity type semiconductor layer 204 in the vicinity of the first facet E1 or the second facet E2 may be narrower than a width of another part of the first conductivity type semiconductor layer 204. The term “same” means being the same within the range of manufacturing fluctuations.

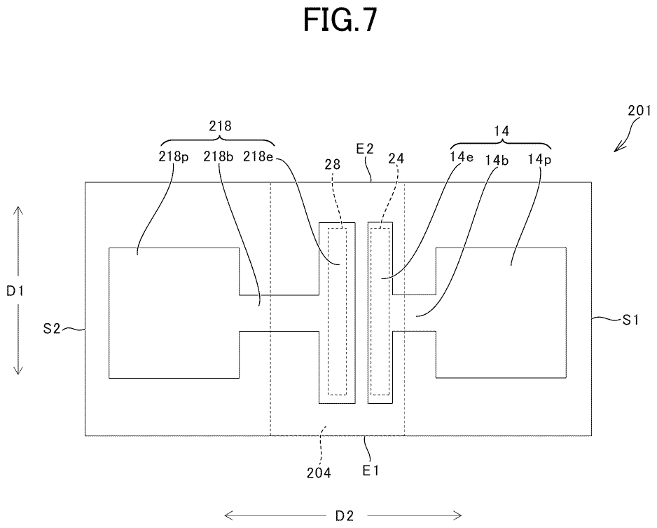

FIG. 7 is a top view of a semiconductor optical modulator 201 according to a modification example of the second example implementation. For the sake of description, the first conductivity type semiconductor layer 204 is indicated as a perspective view by the broken lines. Similarly, the first connection region 24 and the second connection region 28 are also indicated as a perspective view by the broken lines.

The difference between this modification example and the second example implementation resides in a shape of a second electrode 218. The second electrode 218 includes a second conducting electrode portion 218e, a second bridge electrode portion 218b, and a second pad electrode portion 218p. The second conducting electrode portion 218e is arranged above the second connection region 28. The second bridge electrode portion 218b is continuous with the second conducting electrode portion 218e and extends in the width direction D2. The second pad electrode portion 218p is continuous with the second bridge electrode portion 218b. The second pad electrode portion 218p is arranged above the buried layer 10. The second pad electrode portion 218p is connected to external electric wiring (not shown). A dimension of the second bridge electrode portion 218b in the extending direction D1 is smaller than dimensions of the second conducting electrode portion 218e and the second pad electrode portion 218p in the extending direction D1.

The side surface of the first conductivity type semiconductor layer 204 on the left side does not reach the second side surface S2. Thus, in some cases, a step portion is generated in the surface of the buried layer 10 as illustrated in FIG. 5. This step portion connects an upper stage portion formed to correspond to the second lateral portion and a lower stage portion positioned below the upper stage portion. In the second example implementation, the step portion is a part inclined from the upper stage portion toward the lower stage portion. When the second pad electrode portion 218p overlaps the step portion, the second pad electrode portion 218p is not flat, and there is a fear that the connection performance between the second pad electrode portion 218p and the external electric wiring is reduced. Accordingly, in this modification example, the second pad electrode portion 218p is arranged at a position not overlapping the step portion. In other words, in plan view, the step portion overlaps the second bridge electrode portion 218b. The same holds true also on the first side surface S1 side, and, in plan view, the step portion overlaps the first bridge electrode portion 14b.

In this case, in plan view, each of the first pad electrode portion 14p and the second pad electrode portion 218p has a rectangular shape, but the present invention is not limited thereto. Each of the first pad electrode portion 14p and the second pad electrode portion 218p may have a polygonal shape or a shape including a curve.

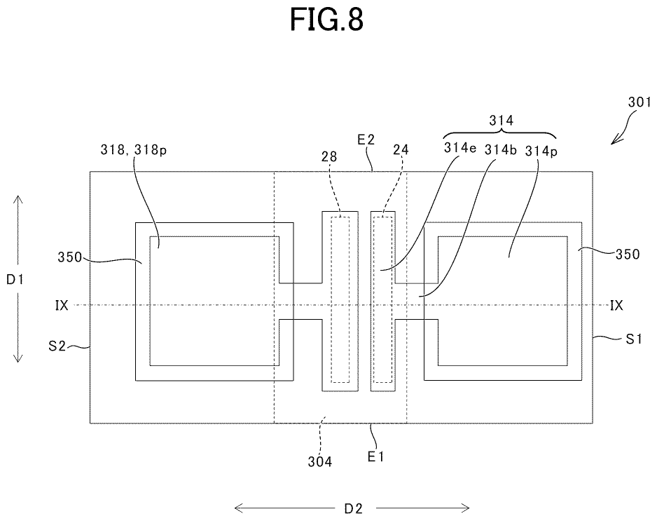

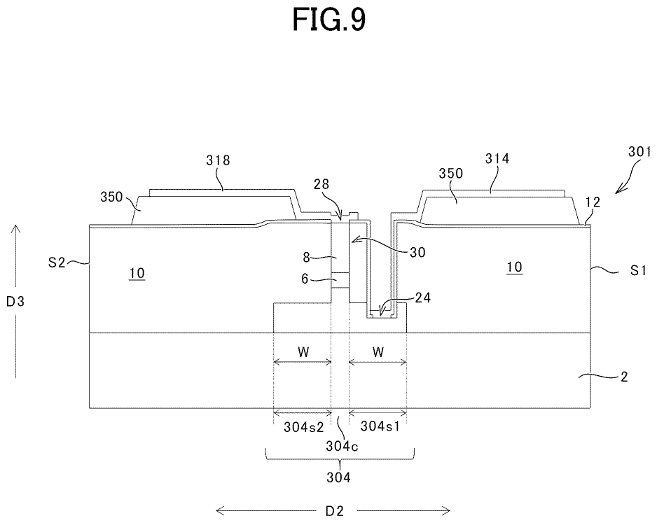

FIG. 8 is a top view of a semiconductor optical modulator 301 according to a third example implementation of the present invention. FIG. 9 is a cross-sectional view for schematically illustrating a cross section taken along the line IX-IX of FIG. 8. The difference between the semiconductor optical modulator 301 according to the third example implementation and the semiconductor optical modulator 201 according to the second example implementation resides in that a resin layer 350 is arranged between the buried layer 10 and each of the first electrode and the second electrode.

A first conductivity type semiconductor layer 304 includes, similarly to the second example implementation, a middle portion 304c, and a first lateral portion 304s1 and a second lateral portion 304s2 provided on respective sides of the middle portion 304c. In plan view, a second pad electrode portion 318p overlaps the step portion of the buried layer 10. In this case, the resin layer 350 is arranged between the second pad electrode portion 318p and the buried layer 10, and hence the second pad electrode portion 318p does not have such a step that affects connection to the external electric wiring.

The resin layer 350 is formed by applying a resin in a soft state to the upper surface of the buried layer 10 and performing etching after curing the resin. The resin layer 350 absorbs the step of the buried layer 10, and hence the step on the surface of the resin layer 350 is reduced. Accordingly, the second pad electrode portion 318p can be arranged at a position overlapping the step portion of the buried layer 10 without separating the second pad electrode portion 318p away from the mesa structure 30. In this manner, the second pad electrode portion 318p and the mesa structure 30 can be brought close to each other, and hence an interval between the second pad electrode portion 318p and the second connection region 28 can be reduced, resulting in that a parasitic capacitance and a parasitic inductance can be reduced. The reduction in parasitic capacitance and parasitic inductance leads to improvement in frequency characteristic. The resin layer 350 is also arranged between a first pad electrode portion 314p and the buried layer 10, and hence this effect of reducing the parasitic capacitance and the parasitic inductance is similarly obtained also in the first pad electrode portion 314p.

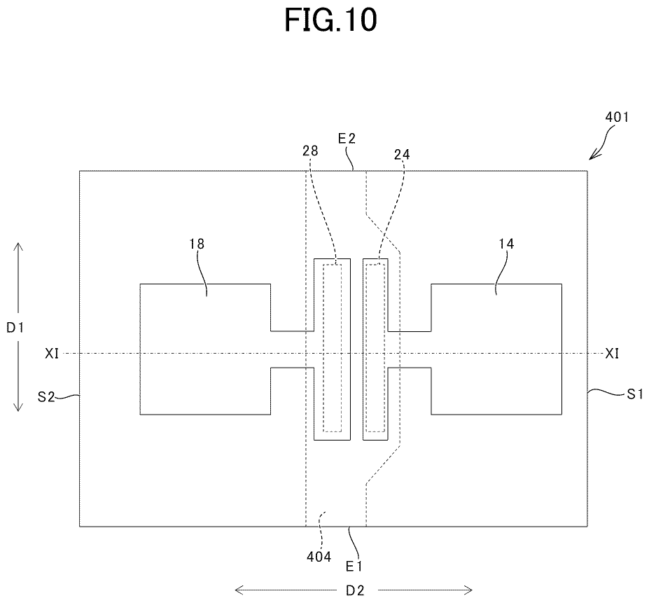

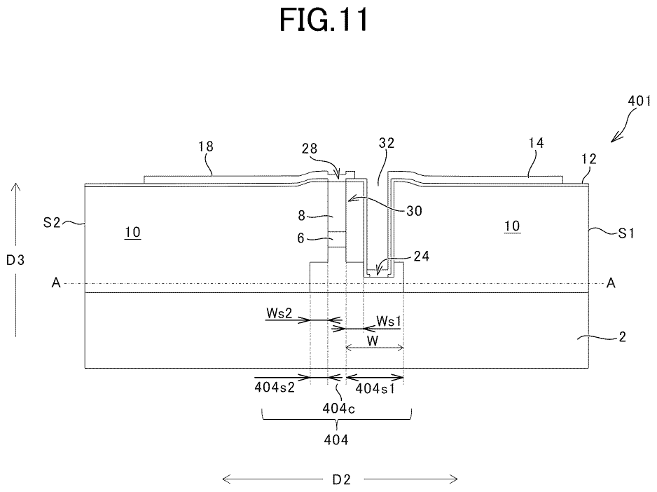

FIG. 10 is a top view of a semiconductor optical modulator 401 according to a fourth example implementation of the present invention. FIG. 11 is a cross-sectional view for schematically illustrating a cross section taken along the line XI-XI of FIG. 10. The difference between the semiconductor optical modulator 401 according to the fourth example implementation and the semiconductor optical modulator according to other example implementations resides in a shape of a first conductivity type semiconductor layer 404.

The first conductivity type semiconductor layer 404 includes a middle portion 404c, a first lateral portion 404s1, and a second lateral portion 404s2. The middle portion 404c is formed of a part forming the mesa structure 30, and a part which is continuous with a lower side of the part forming the mesa structure 30 and has the same width as the width of the mesa structure 30. The first lateral portion 404s1 is provided in the first connection region 24 in plan view, and is continuous with the middle portion 404c on the right side of the mesa structure 30. The second lateral portion 404s2 is continuous with the middle portion 404c on the left side of the mesa structure 30. The first lateral portion 404s1 is in contact with the first electrode 14 in the first connection region 24. The second lateral portion 404s2 is not in contact with any electrode. In the fourth example implementation, a width of the first lateral portion 404s1 and a width of the second lateral portion 404s2 are different from each other. Here, the width of the second lateral portion 404s2 is represented by Ws2. Ws2 is narrower than the width W of the first lateral portion 404s1.

As described in the second example implementation, it is preferred that the first conductivity type semiconductor layer 404 have a shape symmetrical in the width direction D2 with respect to the middle portion 404c. However, a region particularly important for epitaxial growth of the buried layer 10 is a region right next to the mesa structure 30. When members having the same height (first lateral portion 404s1 and second lateral portion 404s2) are arranged in this region, the buried layer 10 can be epitaxially grown with a sufficiently high quality. As described above, it is preferred that the size of the first conductivity type semiconductor layer 404 be smaller, and, from this viewpoint, it is preferred that the width of the second lateral portion 404s2 be narrower than the width of the first lateral portion 404s1. For example, it is sufficient from the viewpoint of crystal quality that a difference between the width Ws2 of the second lateral portion 404s2 and a width Ws1 of a part of the first lateral portion 404s1 between the first mesa side surface which is the side surface of the mesa structure 30 on the right side and a side surface of the groove portion 32 directed to the first mesa side surface side falls within 20% of Ws2.

Further, a width of a part of the first conductivity type semiconductor layer 404 in the vicinity of each of the first facet E1 and the second facet E2 is narrower than a width of another part of the first conductivity type semiconductor layer 404. Further, the first conductivity type semiconductor layer 404 is shaped so that the width gradually changes in the width direction D2. However, the shape of the change of the width is not limited thereto, and the width may be changed in a curved shape or a stepped shape. Further, the width may be changed only on any one facet side. The shape of the first conductivity type semiconductor layer in plan view is applicable not only in the fourth example implementation, but also in other example implementations described above and below.

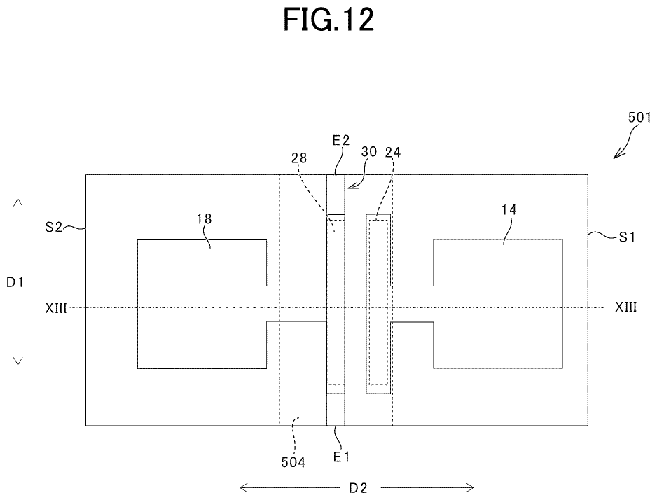

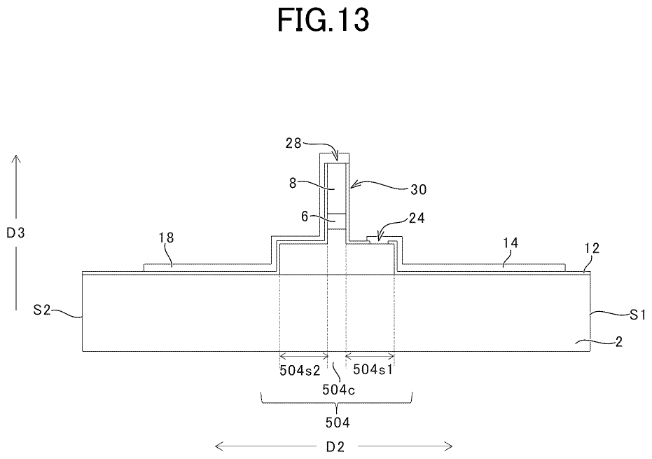

FIG. 12 is a top view of a semiconductor optical modulator 501 according to a fifth example implementation of the present invention. FIG. 13 is a cross-sectional view for schematically illustrating a cross section taken along the line XIII-XIII of FIG. 12. The difference between the semiconductor optical modulator 501 according to the fifth example implementation and the semiconductor optical modulator 201 according to the second example implementation resides in that there is no buried layer 10.

Similarly to other example implementations, in the fifth example implementation, a first conductivity type semiconductor layer 504 is arranged on the substrate 2, and the mesa structure 30 is formed thereon. The first conductivity type semiconductor layer 504 includes a middle portion 504c formed of a part forming the mesa structure 30 and a part which is continuous with a lower side of the part forming the mesa structure 30 and has the same width as the width of the mesa structure 30. Further, the first conductivity type semiconductor layer 504 includes a first lateral portion 504s1 and a second lateral portion 504s2 in the width direction D2. The first lateral portion 504s1 is provided in the first connection region 24 in plan view, and is continuous with the middle portion 504c on the right side of the mesa structure 30. The second lateral portion 504s2 is continuous with the middle portion 504c on the left side of the mesa structure 30. The insulating film 12 is arranged on an upper surface of the substrate 2, an upper surface of the first lateral portion 504s1, and an upper surface of the second lateral portion 504s2. Further, the insulating film 12 is not arranged in the first connection region 24 in which the first electrode 14 and the first lateral portion 504s1 are brought into contact with each other. The insulating film 12 is not arranged in the second connection region 28 in which the second conductivity type semiconductor layer 8 and the second electrode 18 are brought into contact with each other.

Similarly to other example implementations, in the fifth example implementation, a width of the first conductivity type semiconductor layer 504 is narrower than a width of the semiconductor optical modulator 501. In this manner, the difference between the frequency characteristic of the first transmission route and the frequency characteristic of the second transmission route is reduced, resulting in that a semiconductor optical modulator having an excellent high-frequency characteristic is achieved.

Similarly to the first conductivity type semiconductor layer 4 of the first example implementation, the first conductivity type semiconductor layer 504 is not required to include the second lateral portion 504s2.

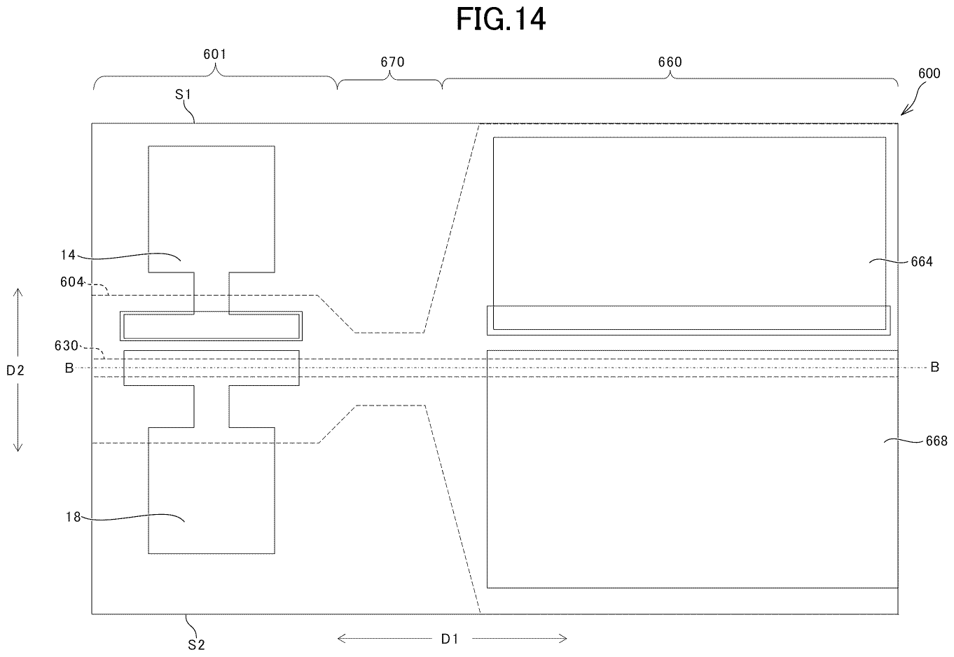

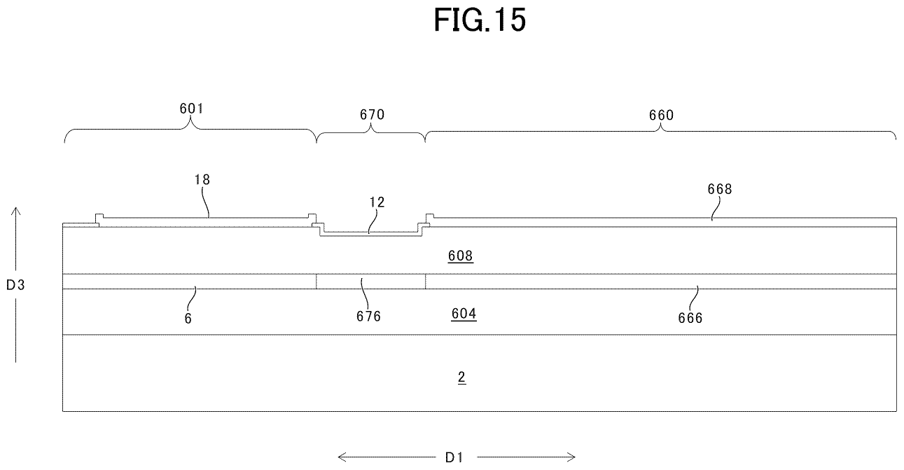

FIG. 14 is a top view of a semiconductor optical integrated device 600 according to a sixth example implementation of the present invention. FIG. 15 is a cross-sectional view for schematically illustrating a cross section taken along the line B-B of FIG. 14. The semiconductor optical integrated device 600 has a structure in which, on the substrate 2, a semiconductor optical modulator 601 having the same structure as that of the semiconductor optical modulator 201 according to the second example implementation, a laser section 660, and a waveguide section 670 are integrated. However, the semiconductor optical modulator 601 may be a semiconductor optical modulator according to an example implementation other than the second example implementation. A mesa structure 630 is formed across the semiconductor optical modulator 601, the waveguide section 670, and the laser section 660. A buried layer is arranged on lateral sides of the mesa structure 630 on the width direction D2 side.

The laser section 660 includes, on the substrate 2, a first conductivity type semiconductor layer 604, an active layer 666, and a second conductivity type semiconductor layer 608. In the buried layer, a groove portion is formed so as to reach the first conductivity type semiconductor layer 604, and a first laser-section electrode 664 is in contact with the first conductivity type semiconductor layer 604 in a bottom surface of the groove portion. Further, on an upper surface of the mesa structure 630, a second laser-section electrode 668 is in contact with the second conductivity type semiconductor layer 608. The laser section 660 emits continuous light in accordance with a voltage applied between the two electrodes (injection of a current).

The waveguide section 670 includes, on the substrate 2, the first conductivity type semiconductor layer 604, a waveguide layer 676, and the second conductivity type semiconductor layer 608. The waveguide section 670 transmits the output light of the laser section 660 to the semiconductor optical modulator 601.

A boundary between the semiconductor optical modulator 601 and the waveguide section 670 is defined by an interface between the optical functional layer 6 and the waveguide layer 676. Further, a boundary between the waveguide section 670 and the laser section 660 is defined by an interface between the waveguide layer 676 and the active layer 666.

The first conductivity type semiconductor layer 604 is a layer shared by the semiconductor optical modulator 601, the waveguide section 670, and the laser section 660. However, the width of the first conductivity type semiconductor layer 604 is different in each of the semiconductor optical modulator 601, the waveguide section 670, and the laser section 660. For the sake of description, in FIG. 14, the first conductivity type semiconductor layer 604 is indicated by the broken lines. In the semiconductor optical modulator 601, the first conductivity type semiconductor layer 604 does not reach the first side surface S1 and the second side surface S2. In this case, the first side surface S1 and the second side surface S2 are each a facet of the semiconductor optical integrated device 600 in the width direction D2. Similarly, in the waveguide section 670, the first conductivity type semiconductor layer 604 does not reach the first side surface S1 and the second side surface S2. The width of the first conductivity type semiconductor layer 604 in the waveguide section 670 is narrower than the width of the first conductivity type semiconductor layer 604 in the semiconductor optical modulator 601. Meanwhile, in the laser section 660, the first conductivity type semiconductor layer 604 is provided from the first side surface S1 to reach the second side surface S2. The width of the first conductivity type semiconductor layer 604 gradually changes in the vicinity of the boundary between the semiconductor optical modulator 601 and the waveguide section 670 and the vicinity of the boundary between the waveguide section 670 and the laser section 660. It is desired that a part of the first conductivity type semiconductor layer 604 in which the width thereof gradually changes not overlap in plan view a connection region (first connection region) between the first electrode 14 and the first conductivity type semiconductor layer 604 and a connection region between the first laser-section electrode 664 and the first conductivity type semiconductor layer 604.

In the waveguide section 670, narrowing the width of the first conductivity type semiconductor layer 604 leads to increasing an electrical isolation between the semiconductor optical modulator 601 and the laser section 660. Further, the second conductivity type semiconductor layer 608 is a layer shared by the semiconductor optical modulator 601, the waveguide section 670, and the laser section 660. In this case, a thickness (dimension in the stacking direction D3) of the second conductivity type semiconductor layer 608 in the waveguide section 670 is smaller than a thickness of the second conductivity type semiconductor layer 608 in the semiconductor optical modulator 601 and the laser section 660. As described above, reducing the thickness of the second conductivity type semiconductor layer 608 in the waveguide section 670 so as to be smaller than the thickness of the second conductivity type semiconductor layer 608 in the semiconductor optical modulator 601 and the laser section 660 also leads to increasing the electrical isolation between the semiconductor optical modulator 601 and the laser section 660.

In the laser section 660, the first conductivity type semiconductor layer 604 is arranged from the first side surface S1 to reach the second side surface S2, but the second conductivity type semiconductor layer 608 is arranged only in the mesa structure 630. Thus, the frequency characteristic from the first laser-section electrode 664 to the active layer 666 and the frequency characteristic from the second laser-section electrode 668 to the active layer 666 are greatly different from each other. However, the laser section 660 operates in DC operation, and hence this difference in frequency characteristic does not affect the characteristic of the laser section 660. In the laser section 660, the first conductivity type semiconductor layer 604 is not required to reach the first side surface S1 and the second side surface S2.

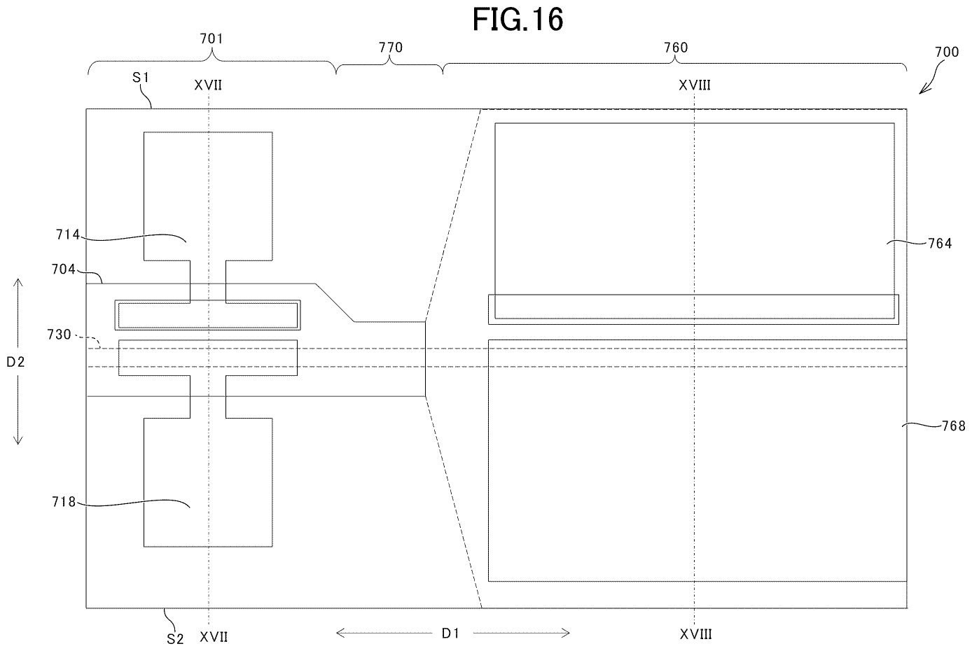

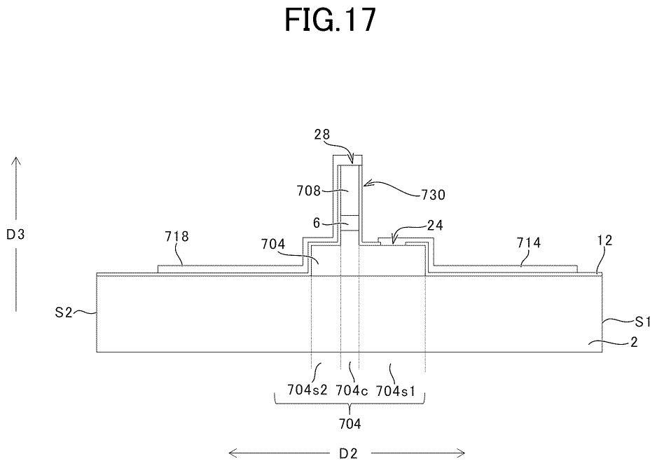

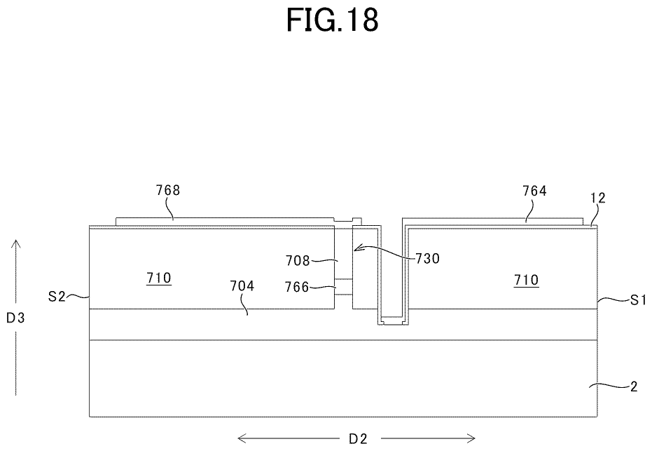

FIG. 16 is a top view of a semiconductor optical integrated device 700 according to a seventh example implementation of the present invention. FIG. 17 is a cross-sectional view for schematically illustrating a cross section taken along the line XVII-XVII of FIG. 16. FIG. 18 is a cross-sectional view for schematically illustrating a cross section taken along the line XVIII-XVIII of FIG. 16. Similarly to the sixth example implementation, in the seventh example implementation, on the substrate 2, a semiconductor optical modulator 701, a waveguide section 770, and a laser section 760 are integrated. A mesa structure 730 is formed across the semiconductor optical modulator 701, the waveguide section 770, and the laser section 760.

The semiconductor optical modulator 701 includes a semiconductor multilayer including a first conductivity type semiconductor layer 704, the optical functional layer 6, and a second conductivity type semiconductor layer 708 which are grown in the stated order on the substrate 2. The first conductivity type semiconductor layer 704 includes a middle portion 704c, a first lateral portion 704s1, and a second lateral portion 704s2. The middle portion 704c is formed of a part forming the mesa structure 730 and a part which is continuous with a lower side of the part forming the mesa structure 730 and has the same width as the width of the mesa structure 730. The first lateral portion 704s1 is provided in the first connection region 24 in plan view, and is continuous with the middle portion 704c on the right side of the mesa structure 730. The second lateral portion 704s2 is continuous with the middle portion 704c on the left side of the mesa structure 730. In this case, the width of the second lateral portion 704s2 is narrower than the width of the first lateral portion 704s1. However, the present invention is not limited thereto, and, similarly to other example implementations, the width of the second lateral portion 704s2 and the width of the first lateral portion 704s1 may be the same. Further, the second lateral portion 704s2 is not required to be arranged. Further, on lateral sides of the mesa structure 730 of the semiconductor optical modulator 701, the insulating film 12 is arranged, and no buried layer 710 is arranged.

The laser section 760 has a structure in which the first conductivity type semiconductor layer 704, an active layer 766, and the second conductivity type semiconductor layer 708 are grown in the stated order on the substrate 2. In the laser section 760, the first conductivity type semiconductor layer 704 is provided from the first side surface S1 to reach the second side surface S2. That is, the width of the first conductivity type semiconductor layer 704 and the width of the laser section 760 are the same. The buried layer 710 is arranged at side surfaces of the mesa structure 730 of the laser section 760. In the buried layer 710, a groove portion provided to reach the first conductivity type semiconductor layer 704 is formed, and a first laser-section electrode 764 is in contact with the first conductivity type semiconductor layer 704 in a bottom surface of the groove portion. Further, on an upper surface of the mesa structure 730, a second laser-section electrode 768 is in contact with the second conductivity type semiconductor layer 708.

The first conductivity type semiconductor layer 704 is a layer shared by the semiconductor optical modulator 701, the waveguide section 770, and the laser section 760. However, the width of the first conductivity type semiconductor layer 704 is different in each of the semiconductor optical modulator 701, the waveguide section 770, and the laser section 760. The width of the first conductivity type semiconductor layer 704 in the waveguide section 770 is narrower than the widths of the first conductivity type semiconductor layer 704 in the semiconductor optical modulator 701 and the laser section 760. Further, in plan view, a side end of the first conductivity type semiconductor layer 704 on the left side (lower side in FIG. 16) has a straight line shape across the waveguide section 770 and the semiconductor optical modulator 701. Meanwhile, a side end of the first conductivity type semiconductor layer 704 on the right side (upper side in FIG. 16) does not have a straight line shape. The semiconductor optical modulator 701 does not include the buried layer, and hence the width of the first lateral portion 704s1 and the width of the second lateral portion 704s2 are not required to be the same. In the seventh example implementation, the width of the first lateral portion 704s1 and the width of the second lateral portion 704s2 are different. However, the width of the first lateral portion 704s1 and the width of the second lateral portion 704s2 may be different from each other in a structure in which the semiconductor optical modulator 701 includes the buried layer, as in the fourth example implementation. The buried layer 710 is arranged also in the vicinity of a connection portion between the waveguide section 770 and the laser section 760.

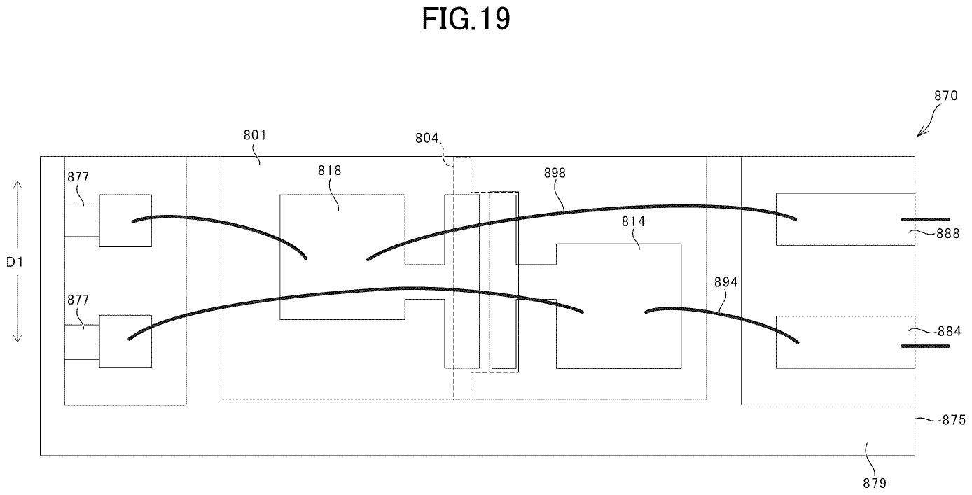

FIG. 19 is a top view of a semiconductor optical apparatus 870 according to an eighth example implementation of the present invention. The semiconductor optical apparatus 870 has a structure in which a semiconductor optical modulator 801 is mounted on a sub-mount 875. The structure of the semiconductor optical modulator 801 according to the eighth example implementation is the same as that of the semiconductor optical modulator 1 according to the first example implementation except that shapes of a first electrode 814 and a second electrode 818 are different. In FIG. 19, for the sake of description, a first conductivity type semiconductor layer 804 is indicated by the broken lines.

The sub-mount 875 has a structure in which a surface of a ceramic substrate is metalized. The sub-mount 875 includes a first transmission line 884 and a second transmission line 888. Electrical signals are applied from the outside to the two transmission lines. The sub-mount 875 includes two matching resistors 877 and a conductive pattern 879. The conductive pattern 879 is connected to a reference potential (ground potential). An electrode for connection to the sub-mount 875 is formed on a back surface of the semiconductor optical modulator 801, and the electrode for connection and the conductive pattern 879 are connected to each other with solder.

A center position of a pad electrode portion of the first electrode 814 and a center position of a pad electrode portion of the second electrode 818 are shifted from each other in the extending direction D1. The first transmission line 884 is connected to the pad electrode portion of the first electrode 814 via a first wire 894. The second transmission line 888 is connected to the pad electrode portion of the second electrode 818 via a second wire 898. In this case, the first electrode 814 and the second electrode 818 are arranged so that the second wire 898 becomes longer than the first wire 894. For example, there is assumed a case in which a pair of differential signals are transmitted to the first transmission line 884 and the second transmission line 888. In this case, it is preferred that two electrical signals forming the pair of differential signals be transmitted to the optical functional layer 6 with the same signal quality. As described above, the frequency characteristic of the first transmission route and the frequency characteristic of the second transmission route are different from each other due to a difference between the size of the first conductivity type semiconductor layer 4 and the size of the second conductivity type semiconductor layer 8. This difference is reduced in the above-mentioned example implementations, but the difference may be further reduced by adjusting the wire length as in the eighth example implementation. That is, in the second transmission route that passes through the second conductivity type semiconductor layer 8 that is smaller than the first conductivity type semiconductor layer 4, when the wire through which the electrical signal from the outside is transmitted is intentionally increased in length, the frequency characteristic of the first transmission route and the frequency characteristic of the second transmission route can be brought close to each other in total. Thus, in the eighth example implementation, the second wire 898 is longer than the first wire 894.

The semiconductor optical modulator 801 may have a structure similar to that of the semiconductor optical modulators described in other example implementations. Further, in the semiconductor optical apparatus 870, a semiconductor optical integrated device similar to the semiconductor optical integrated device according to the fifth example implementation or the seventh example implementation may be mounted. At this time, similar effects can be obtained by setting the length of the wire connected to the second electrode of each semiconductor optical modulator so as to be longer than the length of the wire connected to the first electrode.

The present invention is not limited only to the example implementations described above. In the above-mentioned example implementations, a case in which the substrate 2 is a semi-insulating semiconductor substrate has been exemplified, but a conductive substrate may be used. However, in a case of using a conductive substrate, a semi-insulating semiconductor layer is arranged between the conductive substrate and the first conductivity type semiconductor layer. Further, the semiconductor optical modulator is not limited to an electro-absorption modulator, and may be a direct-modulation laser. However, in a case of a semiconductor optical integrated device in which the semiconductor optical modulator is integrated with a laser section, it is preferred that the semiconductor optical modulator be an electro-absorption modulator. In the above-mentioned example implementations, a case in which the electrical signal applied to the semiconductor optical modulator is a differential signal has been exemplified, but the electrical signal may be applied to the semiconductor optical modulator in single-end drive. The first conductivity type semiconductor layer may have a width that varies between each of the middle portion and the lateral portion and another part. For example, a width of a part of the first conductivity type semiconductor layer in the vicinity of the facet may be narrower or wider than the widths of the middle portion and the lateral portion. Further, the width of not only the part at the facet but also a part of the first conductivity type semiconductor layer in the vicinity of connection to the waveguide section may be different from a width of another part.

The present invention provides a semiconductor optical modulator including a first conductivity type semiconductor layer, an optical functional layer, and a second conductivity type semiconductor layer. In the semiconductor optical modulator, a difference between a frequency characteristic from the first conductivity type semiconductor layer to the optical functional layer and a frequency characteristic from the second conductivity type semiconductor layer to the optical functional layer is reduced. A part of the first conductivity type semiconductor layer, the optical functional layer, and the second conductivity type semiconductor layer form a mesa structure. The first conductivity type semiconductor layer is in contact with a first electrode in a first connection region, and the second conductivity type semiconductor layer is in contact with a second electrode on an upper surface of the mesa structure. The first conductivity type semiconductor layer includes: a middle portion formed of a part forming the mesa structure and a part which is continuous with a lower side of the part forming the mesa structure and has the same width as a width of the mesa structure; and a first lateral portion which is provided in the first connection region in plan view and is continuous with the middle portion on one side of the mesa structure. A side surface of the first lateral portion is arranged on an inner side with respect to a side surface of the semiconductor optical modulator on the one side. A width of the first lateral portion is preferably ⅓ or less of an interval between a first mesa side surface which is a side surface of the mesa structure on the one side and a first side surface which is the side surface of the semiconductor optical modulator on the one side, and is more preferably ¼ or less of the interval. The first conductivity type semiconductor layer may include a second lateral portion continuous with the middle portion on another side of the mesa structure. A difference between the width of the first lateral portion and a width of the second lateral portion may fall within 20% of the width of the first lateral portion. Further, a difference between the width of the second lateral portion and a width of a part of the first lateral portion between the first mesa side surface which is the side surface of the mesa structure on the one side and a side surface of a groove portion directed to the first mesa side surface side may fall within 20% of the width of the second lateral portion. On a lateral side of the mesa structure, a buried layer may be arranged, or an insulating film may be arranged. In a case in which the buried layer is arranged on the lateral side of the mesa structure, when a step portion is formed on a surface of the buried layer, it is desired that a pad electrode portion included in the first electrode and/or the second electrode be not arranged in a region of the step portion. A resin layer may be arranged between the pad electrode portion and the buried layer. In a direction in which the mesa structure extends, both ends of the second connection region may be arranged on the inner side of both ends of the first connection region.

The present invention is also applicable to a semiconductor optical integrated device including the semiconductor optical modulator, a laser section, and a waveguide section arranged between the semiconductor optical modulator and the laser section. The first conductivity type semiconductor layer is arranged across the semiconductor optical modulator, the laser section, and the waveguide section. In plan view, the width of the first conductivity type semiconductor layer is narrowest in the waveguide section. Moreover, the present invention is also applicable to a semiconductor optical apparatus including a sub-mount having mounted thereon any one of a semiconductor optical modulator or a semiconductor optical integrated device. The sub-mount includes a first transmission line and a second transmission line. The first transmission line and the first electrode of the semiconductor optical modulator are connected to each other by a first wire, and the second transmission line and the second electrode are connected to each other by a second wire. It is desired that the second wire be longer than the first wire.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor optical modulator, comprising:
a semiconductor multilayer including a first conductivity type semiconductor layer, an optical functional layer, and a second conductivity type semiconductor layer which are grown in the stated order;
a first electrode connected to the first conductivity type semiconductor layer; and
a second electrode connected to the second conductivity type semiconductor layer,
wherein a part of the first conductivity type semiconductor layer, the optical functional layer, and the second conductivity type semiconductor layer form a mesa structure extending in an extending direction, and
wherein the first conductivity type semiconductor layer has a width narrower than a width of the semiconductor optical modulator.

2. The semiconductor optical modulator according to claim 1, wherein the first electrode and the second electrode are arranged on a surface of the semiconductor optical modulator.

3. The semiconductor optical modulator according to claim 2,
wherein, in plan view, the first electrode and the first conductivity type semiconductor layer are connected to each other in a first connection region, and
wherein the first conductivity type semiconductor layer includes:
a middle portion which has the part forming the mesa structure, and a part which is continuous with a lower side of the part forming the mesa structure and has the same width as a width of the mesa structure; and
a first lateral portion which is provided in the first connection region in plan view and is continuous with the middle portion on one side of the mesa structure.

4. The semiconductor optical modulator according to claim 3, wherein the first lateral portion has a width W that is ⅓ or less of an interval Wa between a first mesa side surface which is a side surface of the mesa structure on the one side and a first side surface which is a side surface of the semiconductor optical modulator on the one side.

5. The semiconductor optical modulator according to claim 3, wherein the first conductivity type semiconductor layer includes a second lateral portion continuous with the middle portion on another side of the mesa structure.

6. The semiconductor optical modulator according to claim 5, wherein a difference between a width of the first lateral portion and a width of the second lateral portion falls within 20% of the width of the first lateral portion.

7. The semiconductor optical modulator according to claim 5, further comprising:
a first buried layer in contact with an upper surface of the first lateral portion and a first mesa side surface which is a side surface of the mesa structure on the one side; and
a second buried layer in contact with an upper surface of the second lateral portion and a second mesa side surface which is a side surface of the mesa structure on the another side,
wherein an upper surface of the second buried layer includes an upper stage portion corresponding to the second lateral portion, a lower stage portion positioned below the upper stage portion, and a step portion connecting the upper stage portion and the lower stage portion to each other.

8. The semiconductor optical modulator according to claim 7,
wherein the second electrode includes:
a conducting electrode portion arranged in a second connection region in which the second electrode and the second conductivity type semiconductor layer are connected to each other in plan view;
a bridge electrode portion which is continuous with the conducting electrode portion and extends in a width direction of the mesa structure; and
a pad electrode portion continuous with the bridge electrode portion,
wherein a dimension of the bridge electrode portion in the extending direction is smaller than dimensions of the conducting electrode portion and the pad electrode portion in the extending direction, and
wherein, in plan view, the step portion of the second buried layer overlaps the bridge electrode portion.

9. The semiconductor optical modulator according to claim 7,
wherein the second electrode includes:
a conducting electrode portion arranged in a second connection region in which the second electrode and the second conductivity type semiconductor layer are connected to each other in plan view;
a bridge electrode portion which is continuous with the conducting electrode portion and extends in a width direction of the mesa structure; and
a pad electrode portion continuous with the bridge electrode portion,
wherein a dimension of the bridge electrode portion in the extending direction is narrower than dimensions of the conducting electrode portion and the pad electrode portion in the extending direction,
wherein a resin layer is arranged between the pad electrode portion and the second buried layer, and
wherein the resin layer overlaps the step portion in plan view.

10. The semiconductor optical modulator according to claim 5, further comprising a groove portion provided on the one side of the mesa structure in a width direction of the mesa structure, and has a bottom portion including the first connection region,
wherein a difference between a width of the second lateral portion and a width of a part of the first lateral portion between a first mesa side surface which is a side surface of the mesa structure on the one side and a side surface of the groove portion directed to the first mesa side surface side falls within 20% of the width of the second lateral portion.

11. The semiconductor optical modulator according to claim 1, further comprising an insulating film arranged on a lateral side of the mesa structure.

12. The semiconductor optical modulator according to claim 3, wherein both ends of a second connection region in the extending direction are arranged on an inner side of both ends of the first connection region in the extending direction, the second connection region being a region in which the second electrode and the second conductivity type semiconductor layer are connected to each other in plan view.

13. A semiconductor optical integrated device, comprising:
a semiconductor optical modulator comprising:
a semiconductor multilayer including a first conductivity type semiconductor layer, an optical functional layer, and a second conductivity type semiconductor layer which are grown in the stated order;
a first electrode connected to the first conductivity type semiconductor layer; and
a second electrode connected to the second conductivity type semiconductor layer,
wherein a part of the first conductivity type semiconductor layer, the optical functional layer, and the second conductivity type semiconductor layer form a mesa structure extending in an extending direction, and
wherein the first conductivity type semiconductor layer has a width narrower than a width of the semiconductor optical modulator;
a laser section; and
a waveguide section arranged between the semiconductor optical modulator and the laser section,
wherein the mesa structure extends in the extending direction across the semiconductor optical modulator, the waveguide section, and the laser section.

14. The semiconductor optical integrated device according to claim 13,
wherein the first conductivity type semiconductor layer is arranged to be shared by the semiconductor optical modulator, the waveguide section, and the laser section, and
wherein, in a width direction of the mesa structure, a width of the first conductivity type semiconductor layer in the waveguide section is narrower than a width of the first conductivity type semiconductor layer in the semiconductor optical modulator.

15. The semiconductor optical integrated device according to claim 14, wherein a side surface of the first conductivity type semiconductor layer on one side in the laser section reaches, in the width direction, a side surface of the semiconductor optical integrated device on the one side.

16. The semiconductor optical integrated device according to claim 13, further comprising a buried layer arranged on a lateral side of the mesa structure in the width direction.

17. The semiconductor optical integrated device according to claim 13, further comprising:
an insulating film arranged on a lateral side of the mesa structure in the semiconductor optical modulator in the width direction; and
a buried layer arranged on a lateral side of the mesa structure in the laser section.

18. A semiconductor optical apparatus, comprising:
a semiconductor optical modulator comprising:
a semiconductor multilayer including a first conductivity type semiconductor layer, an optical functional layer, and a second conductivity type semiconductor layer which are grown in the stated order;
a first electrode connected to the first conductivity type semiconductor layer; and
a second electrode connected to the second conductivity type semiconductor layer,
wherein a part of the first conductivity type semiconductor layer, the optical functional layer, and the second conductivity type semiconductor layer form a mesa structure extending in an extending direction, and
wherein the first conductivity type semiconductor layer has a width narrower than a width of the semiconductor optical modulator; and
a sub-mount on which the semiconductor optical modulator is mounted.

19. The semiconductor optical apparatus according to claim 18,
wherein the sub-mount includes a first transmission line and a second transmission line,
wherein the semiconductor optical apparatus further comprises:
a first wire connecting the first transmission line and the first electrode to each other; and
a second wire connecting the second transmission line and the second electrode to each other, and
wherein the second wire is longer than the first wire.
